(19) United States
(12) Patent Application Publication
(10) Pub. No.: US 2023/0244975 A1
(43) Pub. Date: Aug. 3, 2023

(54) QUBIT PROCESSING METHOD AND APPARATUS, AND NON-TRANSITORY COMPUTER READABLE MEDIUM

(71) Applicant: Alibaba Damo (Hangzhou) Technology Co., Ltd., Hangzhou, Zhejiang (CN)

(72) Inventors: Tian XIA, Hangzhou (CN); Huihai ZHAO, Beijing (CN); Feng WU, Hangzhou (CN)

(21) Appl. No.: 18/045,632

(22) Filed: Oct. 11, 2022

(30) Foreign Application Priority Data
Oct. 18, 2021 (CN) 202111206748.3

(51) Int. Cl. G06N 10/20

(52) U.S. Cl. CPC G06N 10/20

(57) ABSTRACT

Qubit processing methods and apparatus, and a non-transitory computer readable medium are provided. The method includes determining a plurality of parts included in a qubit; determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and performing summation on the electromagnetic parameters of the surfaces of the plurality of parts to obtain an electromagnetic parameter of the qubit.

### CROSS-REFERENCE TO RELATED APPLICATIONS

The disclosure claims the benefits of priority to Chinese Application No. 202111206748.3, filed Oct. 18, 2021, which is incorporated herein by reference in its entirety.

### TECHNICAL FIELD

The present disclosure relates to the field of quantum computing, and specifically, to a qubit processing method and apparatus, and a non-transitory computer readable medium.

### BACKGROUND

During the design and simulation of qubits, an electromagnetic calculation method is required to extract quantum circuit parameters, and to calculate the distribution of electromagnetic fields in the environment to analyze quantum state decoherence. Accurate and efficient electromagnetic simulation can effectively facilitate the design of quantum chips and achieve bits with high decoherence time by design.

Generally, calculation is mostly performed by using the finite element method (FEM) in the current qubit simulations. In electromagnetic simulation, the FEM requires three-dimensional mesh subdivision on the structure and environment and large matrix equations solution. During mesh subdivision, the structure and environment may be divided into a large quantity of three-dimensional structures, such as tetrahedra. Material parameters in the structure and environment are defined in each tetrahedron to achieve a relatively accurate description of the environment. After the subdivision, a limited quantity of tetrahedra are used as the smallest elements for carrying the electromagnetic field, which can be solved by bring into the Maxwell's equation. However, when the foregoing solution is used to resolve a problem, a large quantity of smallest elements will be generated due to the design of the subdivision in the three-dimensional volume, which will lead to a relatively large quantity of unknowns to be calculated.

### SUMMARY OF THE DISCLOSURE

Embodiments of the present disclosure provide qubit processing methods. The methods can include determining a plurality of parts included in a qubit; determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and performing summation on the electromagnetic parameters of the surfaces of the plurality of parts to obtain an electromagnetic parameter of the qubit.

Embodiments of the present disclosure provide an apparatus for performing qubit processing. The apparatus includes a memory configured to store instructions; and one or more processors configured to execute the instructions to cause the apparatus to perform determining a plurality of parts included in a qubit; determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and performing summation on the electromagnetic parameters of the surfaces of the plurality of parts to obtain an electromagnetic parameter of the qubit.

Embodiments of the present disclosure provide a non-transitory computer readable medium that stores a set of instructions that is executable by one or more processors of an apparatus to cause the apparatus to initiate a method for performing qubit processing. The method includes determining a plurality of parts included in a qubit; determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and performing summation on the electromagnetic parameters of the surfaces of the plurality of parts to obtain an electromagnetic parameter of the qubit.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 is a structural block diagram of hardware of an exemplary computer terminal configured to implement a qubit processing method, according to some embodiments of the present disclosure.

FIG. 2 is a flowchart of an exemplary qubit processing method, according to some embodiments of the present disclosure.

FIG. 3 is a flowchart of another exemplary qubit processing method, according to some embodiments of the present disclosure.

FIG. 4A is a flowchart of an exemplary method for electric field occupation ratio calculation, according to some embodiments of the present disclosure.

FIG. 4B is an efficiency comparison diagram obtained based on a method for calculating an electric field occupation ratio, according to some embodiments of the present disclosure.

FIG. 5 is a schematic diagram of a capacitance calculation, according to some embodiments of the present disclosure.

FIG. 6A is a schematic effect diagram of using an integral equation method in a capacitance calculation method, according to some embodiments of the present disclosure.

FIG. 6B is a schematic effect diagrams of using an FEM in a capacitance calculation method, according to some embodiments of the present disclosure.

FIG. 7A is a flowchart of an exemplary capacitance calculation method, according to some embodiments of the present disclosure.

FIG. 7B illustrates a process of calculation for extracting a capacitance parameter in a capacitance calculation method, according to some embodiments of the present disclosure.

FIG. 8 is a schematic diagram of efficiency obtained based on a capacitance calculation method, according to some embodiments of the present disclosure.

FIG. 9 is a schematic diagram of a uniform refinement solution in a mesh refinement method, according to some embodiments of the present disclosure.

FIG. 10 is a schematic diagram of a boundary refinement solution in a mesh refinement method, according to some embodiments of the present disclosure.

FIG. 11 is a structural block diagram of an exemplary qubit processing apparatus, according to some embodiments of the present disclosure.

FIG. 12 is a structural block diagram of another exemplary qubit processing apparatus, according to some embodiments of the present disclosure.

FIG. 13 is an apparatus block diagram of an exemplary terminal, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

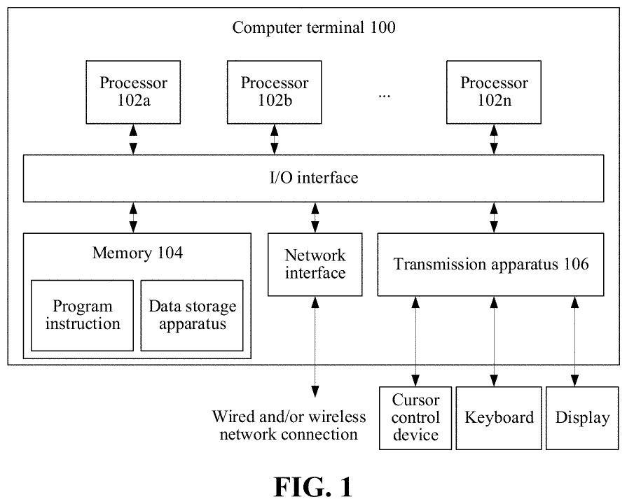

According to some embodiments of the present disclosure, a qubit processing method is provided. The method provided according to some embodiments of the present disclosure may be performed using a mobile terminal, a computer terminal, or a similar computing apparatus. FIG. 1 is a structural block diagram of hardware of a computer terminal (or a mobile device) configured to implement a qubit processing method. As shown in FIG. 1, a computer terminal 100 (or a mobile device) may include one or more (shown as 102a, 102b, . . . , 102n in the figure) processors 102 (the processor may include, but not limited to, a processing apparatus, for example, a microprocessor (MCU) or a programmable logic device (FPGA)), a memory 104 configured to store data, and a transmission apparatus 106 for a communication function. In addition, the computer terminal (or the mobile device) may further include a display, an Input/Output interface (I/O interface), a Universal Serial Bus (USB) port (may be included as one of ports of the bus), a network interface, a power supply and/or a camera. It is appreciated that the structure shown in FIG. 1 is only illustrative, and does not constitute a limitation on the structure of the foregoing computer terminal. For example, the computer terminal 100 may further include more or fewer components than those shown in FIG. 1, or have a configuration different from that shown in FIG. 1.

The one or more processors 102 or other data processing circuits in the context may be generally referred to as a “data processing circuit”. The data processing circuit may be entirely or partly embodied as software, hardware, firmware, or any combination thereof. In addition, the data processing circuit may be an independent processing module, or may be combined into any of other elements in the computer terminal 100 (or the mobile device) entirely or partly. As mentioned in the embodiments of the present disclosure, the data processing circuit is used as a processor control (for example, a selection of a variable resistance terminal path connected to an interface).

The memory 104 may be configured to store a software program and module of application software, for example, a program instruction/data storage apparatus corresponding to the qubit processing method in the embodiments of the present disclosure. The processor 102 runs the software program and module stored in the memory 104, to implement various functional applications and data processing, that is, implement the foregoing qubit processing method of the application. The memory 104 may include a high-speed random access memory, and may also include a non-volatile memory, for example, one or more magnetic storage apparatuses, a flash memory, or another non-volatile solid-state memory. In some embodiments, the memory 104 may further include memories remotely disposed relative to the processor 102, and these remote memories may be connected to the computer terminal 100 through a network. The foregoing examples of the network include, but not limited to, the Internet, an intranet, a local area network, a mobile communication network, and a combination thereof.

The transmission apparatus 106 is configured to receive or send data through a network. In some embodiments, the network may include a wireless network provided by a communication provider of the computer terminal 100. In some embodiments, the transmission apparatus 106 includes a network interface controller (NIC), which may be connected to another network device through a base station so as to communicate with the Internet. In some embodiments, the transmission apparatus 106 may be a radio frequency (RF) module, which is configured to communicate with the Internet in a wireless manner.

The display may be, for example, a touch screen type liquid crystal display (LCD), and the LCD enables the user to interact with a user interface of the computer terminal 100 (or the mobile device).

Some embodiments of the present disclosure provide a qubit processing method using integral equations, which can be performed by the computer terminal 100 shown in FIG. 1. The method can include obtaining electromagnetic parameters of a qubit by performing a two-dimension mesh subdivision on a surface of a plurality of parts of the qubit, and using an integral equation to represent an environment. The environment may include various electromagnetic interactions, and the electromagnetic parameters can include capacitance matrix, electric field occupation ratio, and the like. Different integral equations can be used to present different electromagnetic interactions to obtain different electromagnetic parameters.

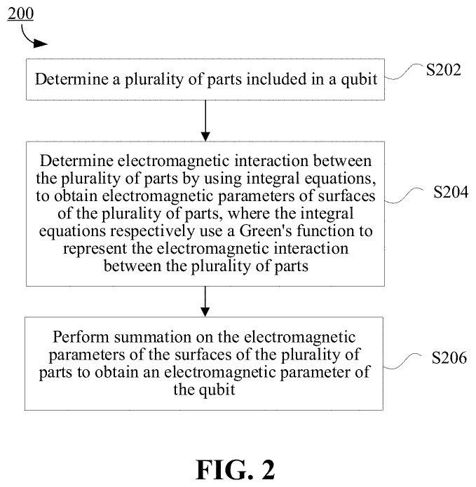

FIG. 2 is a flowchart of an exemplary qubit processing method 200, according to some embodiments of the present disclosure. As shown in FIG. 2, the method includes the steps S202 to S206.

At step S202, a plurality of parts of a qubit are determined.

At step S204, electromagnetic interactions between the plurality of parts are determined by using an integral equation, to obtain electromagnetic parameters of surfaces of the plurality of parts. In some embodiments, Green's function is used to represent the electromagnetic interactions between the plurality of parts for the integral equation.

At step S206, summation on the electromagnetic parameters of the surfaces of the plurality of parts is performed to obtain an electromagnetic parameter of the qubit.

With this method, a plurality of parts in a qubit are determined, and electromagnetic interactions between the plurality of parts are determined by using integral equations to obtain electromagnetic parameters of surfaces of the plurality of parts. By respectively processing the plurality of parts efficiently, and performing summation on the electromagnetic parameters of the surfaces of the plurality of parts, an electromagnetic parameter of the qubit is obtained. Therefore, the technical problem of an excessively long calculation time caused by a large amount of calculation in a qubit simulation process is resolved.

In some embodiments, for example, in a quantum chip, division of the plurality of parts included in the qubit may be performed at a physical level. That is, the quantum chip is divided into a plurality of parts (for example, including two flat plates, control lines, ground, and the like that constitute a qubit). Since the plurality of parts are in a same level, the plurality of parts included in the qubit can be determined. Division may alternatively be performed at other levels, for example, the division can be performed according to the function executed by each part, or the position of each part, which is not limited herein. By determining the plurality of parts included in the qubit, a basis for the subsequent respectively calculation for the plurality of parts of the qubit is provided, so that the single calculation amount is reduced and the calculation is simpler.

In some embodiments, when using integral equations to determine the electromagnetic interactions between the plurality of parts, the integral equations need to be capable of representing the environments and structures in which the plurality of parts are located. The integral equations may be selected flexibly according to the different representation capabilities of the integral equations, or the emphasis of the integral equations in different environments and structures. A matrix may be constructed by using integral equations, so that the electromagnetic interactions between the parts are described by using a numerical method. For example, the Green's function may be used to construct a matrix, and the integral equations corresponding to the plurality of parts may be determined by solving the matrix. The Green's function can represent the structure and environment of the qubit in a corresponding part, and two-dimensional mesh subdivision is performed, to obtain an electromagnetic parameter of the corresponding part. Electromagnetic parameters are obtained by performing calculation of the integral equations for the plurality of parts. During calculation for each part, the quantity of positions to be calculated and calculation amount are greatly reduced, and the calculation efficiency is effectively improved.

It is to be noted that the electromagnetic parameters may refer to various parameters related to the qubit, for example, capacitance, electric field energy of a local loss region of the qubit, electric field energy of the entire space region of the qubit, an electric field occupation ratio (e.g., a ratio of the electric field energy of the local loss region to the total space energy), and the like.

In some embodiments, during the determining electromagnetic interactions between the plurality of parts by using integral equations, to obtain electromagnetic parameters of surfaces of the plurality of parts, the following approach may be used. A two-dimensional mesh subdivision can be performed on the surfaces of the plurality of parts respectively, to obtain a plurality of meshes. The electromagnetic parameters of the plurality of meshes can be calculated by using integral equations to obtain the electromagnetic parameters of the surfaces of the plurality of parts respectively. With this method, the electromagnetic parameters of the surfaces of the plurality of parts can be acquired more accurately and more quickly.

In some embodiments, the performing two-dimensional mesh subdivision on the surfaces of the plurality of parts respectively, to obtain a plurality of meshes includes: performing two-dimensional mesh subdivision on the surfaces of the plurality of parts respectively by using a mixture of a uniform refinement method and a boundary refinement method, to obtain the plurality of meshes. As may be appreciated, accurately and efficiently simulating the qubit simulation may be difficult when only the uniform refinement method or the boundary refinement method is used. Using only the uniform refinement method can lead to an exponential increase of unknowns and increase the calculation burden. Using only the boundary refinement method may impair the calculation accuracy of non-boundary regions. Therefore, a mixture of the uniform refinement method and the boundary refinement method can be used, so that the properties of the meshes can be well-maintained.

In some embodiments, the respectively performing two-dimensional mesh subdivision on the surfaces of the plurality of parts by using a mixture of a uniform refinement method and a boundary refinement method, to obtain the plurality of meshes includes: respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes. The uniform refinement method can be used in the non-boundary regions, and a small quantity of uniform refinement layers can be used to effectively optimize the accuracy of the non-boundary regions and effectively control the quantity of unknowns. The boundary refinement method can be used in the boundary regions, and the mesh subdivision at the boundary can be arbitrarily refined in the vertical direction. This approach can greatly improve the calculation accuracy of the boundary. Furthermore, the unknowns increase linearly and are controlled within a relatively small range.

In some embodiments, the meshes obtained through subdivision are triangular meshes. The triangular meshes obtained through subdivision by using the uniform refinement method have the same aspect ratio. For triangular meshes obtained through subdivision by using the boundary refinement method, an obtained triangular mesh closer to a boundary of the boundary region is smaller, and the triangular meshes have different aspect ratios. In the uniform refinement method, the triangular meshes have the same aspect ratio, and after a plurality of layers of refinement, a plurality of small meshes with a same aspect ratio can be generated, which can maintain the conformality of the meshes, thereby facilitating structured processing. In the boundary refinement method, meshes closer to the boundary are gradually smaller, which can better represent the singularity at the boundary. By using the foregoing two methods, the meshes can be kept conformal locally, thereby improving the calculation accuracy while facilitating control of the quantity of unknowns.

In some embodiments, there are many manners of performing summation on the electromagnetic parameters of the plurality of parts, and an integral equation method is often used. For example, the Gaussian integration method may be used for summation to obtain the electromagnetic parameter of the entire qubit, thereby ensuring completion of acquisition of the electromagnetic parameter of the entire qubit. For example, in a scenario of qubit decoherence, during accurate calculation of the electric field occupation ratio near the surface of a qubit superconducting material, the Gaussian integration method may be used to calculate the electric field occupation ratio in an ultra-thin region. Therefore, the divergence problem of a density of the surface energy of the superconducting material can be effectively resolved, and the calculation is relatively accurate. The accuracy and efficiency of the calculation for the electric field occupation ratio in the qubit can be effectively controlled. The electromagnetic parameter of the qubit can be acquired by simply calculating the electromagnetic parameters of the plurality of parts. After the electromagnetic parameters of the regions are efficiently and accurately calculated, the electromagnetic parameter of the qubit can be calculated simply and accurately, which greatly reduces the amount of calculation and improves the speed of calculation.

In some embodiments, the core design in the quantum chip (qubit) is divided into a plurality of parts: including the two flat plates, control lines, ground, and the like that constitute the bit. The several parts belong to a same level within the chip. Subsequently, a matrix is constructed based on the interactions between the various parts by using an integral equation method, that is, the interactions between the various parts are described by using a numerical method. In the integral equation method, the Green's function is used to represent the structures and environments of the various parts of the qubit in the corresponding levels (that is, features of the (electromagnetic) interactions between the parts). To accurately acquire the numerical expressions of these features, each part may be meshed, and calculation of the Green's function may be performed on the small meshes after the meshing, to obtain a value of each element in the matrix, thereby constructing a complete matrix. By solving this matrix and performing summation on the charges of the plurality of parts, a lumped effect of the interactions between the parts can be obtained.

In a specific scenario, regarding a decoherence problem of the qubit, it is necessary to accurately calculate the electric field occupation ratio near the surface of the qubit superconducting material. By using the scheme mentioned above, the electric field and the electric field occupation ratio near the surface of the superconducting material can be reconstructed. For example, when the Gaussian integration method is used to calculate the electric field occupation ratio in the ultra-thin region, the divergence problem of a density of the surface energy of the superconducting material can be effectively resolved, and the calculation is relatively accurate.

Therefore, the accuracy and efficiency for calculating the electric field occupation ratio in the qubit can be effectively controlled. Compared with using other methods, by using the methods in the foregoing embodiments, the calculation time can be greatly reduced, the calculation accuracy can be significantly improved, and the calculation accuracy can be effectively controlled. In this manner, the disclosed embodiments can address the technical problem of an excessively long calculation time caused by a large amount of calculation in a qubit simulation process.

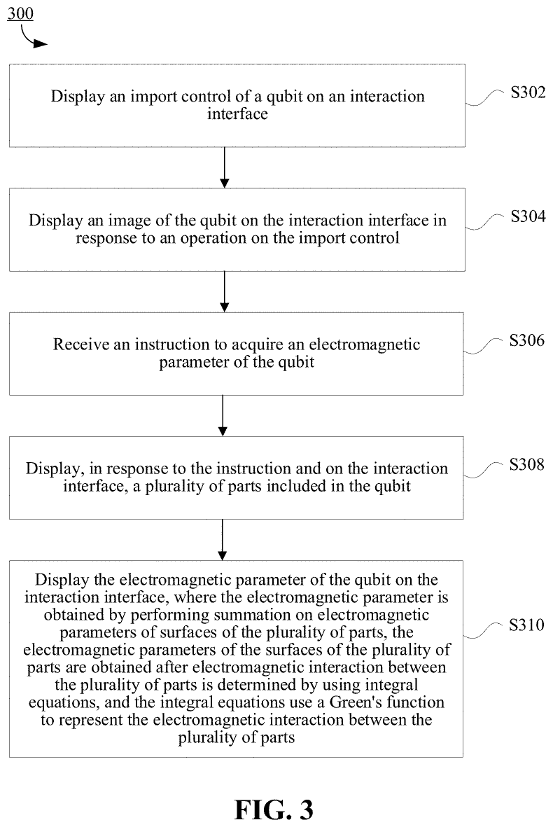

FIG. 3 is a flowchart of another exemplary qubit processing method 300, according to some embodiments of the present disclosure. As shown in FIG. 3, the method 300 includes steps S302 to S310.

At step S302, an import control of a qubit is displayed on an interaction interface.

At step S304, an image of the qubit is displayed on the interaction interface in response to an operation on the import control.

At step S306, an instruction to acquire an electromagnetic parameter of the qubit is received.

At step S308, in response to the instruction and a plurality of parts included in the qubit are displayed on the interaction interface.

At step S310, the electromagnetic parameter of the qubit is displayed on the interaction interface. The electromagnetic parameter is obtained by performing summation on electromagnetic parameters of surfaces of the plurality of parts. The electromagnetic parameters of the surfaces of the plurality of parts are obtained after electromagnetic interactions between the plurality of parts are determined by using integral equations. The integral equations use a Green's function to represent the electromagnetic interactions between the plurality of parts.

Through the foregoing steps, by displaying an import control of a qubit on an interaction interface and in response to an operation on the import control, an image of the qubit can be displayed. Subsequently, by receiving a responding to an instruction to acquire an electromagnetic parameter of the qubit, a plurality of parts included in the qubit are determined. By determining electromagnetic interaction between the plurality of parts by using integral equations, electromagnetic parameters of surfaces of the plurality of parts are obtained. By respectively processing the parts efficiently and performing summation on the electromagnetic parameters of the surfaces of the plurality of parts, an electromagnetic parameter of the qubit is obtained, thereby resolving the technical problem of an excessively long calculation time caused by a large amount of calculation in a qubit simulation process.

For analysis on the qubit decoherence, the electric field occupation ratio, that is, a proportion of the electric field energy of a local loss region to the total space energy, often needs to be calculated. The local loss region is usually nano-sized, and by using the integral equation method, the energy of the local loss region can be efficiently and accurately calculated.

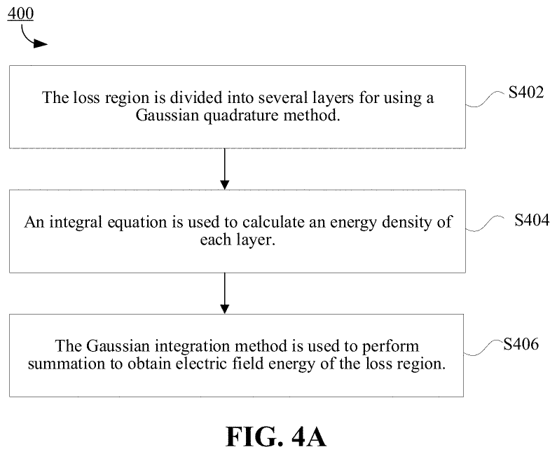

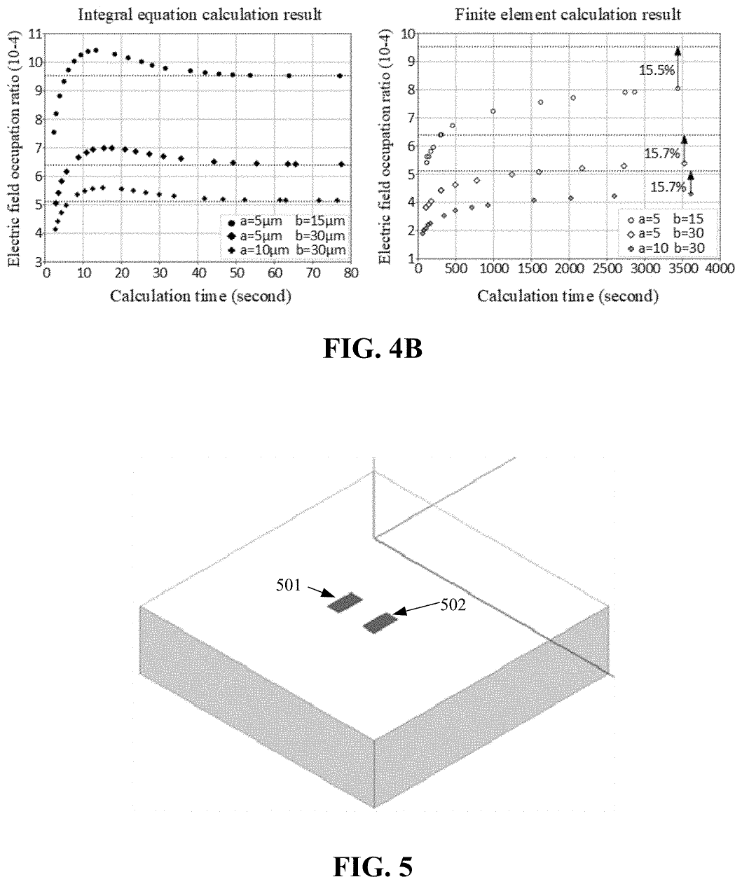

In some embodiments of the present disclosure, a method for superconducting qubit simulation and electric field occupation ratio calculation based on an electrostatic field integral equation is provided. The method accelerates the superconducting qubit simulation and accurately calculates the electric field occupation ratio in a superconducting qubit. FIG. 4A is a flowchart of an exemplary method 400 for electric field occupation ratio calculation, according to some embodiments of the present disclosure. As shown in FIG. 4A, the method 400 includes the steps S402 to S406.

At step S402, the loss region is divided into several layers for using a Gaussian integration method.

At step S404, an integral equation is used to calculate an energy density of each layer.

At step S406, the Gaussian integration method is used to perform summation to obtain electric field energy of the loss region.

FIG. 4B is an efficiency comparison diagram obtained based on a method for calculating an electric field occupation ratio, according to some embodiments of the present disclosure. As shown in FIG. 4B, by using the method 400, the calculation time can be significantly reduced for calculation of the electric field occupation ratio compared with the FEM, and the efficiency can be increased by over 50 times for calculation of the electric field occupation ratio.

In some embodiments, when an integral equation is used to calculate the energy density of each layer, in the integral equation method, the analytical Green's function may be used as a representation function of the environment, so that it is unnecessary to perform mesh subdivision on a three-dimensional structure, and two-dimensional mesh subdivision only needs to be adopted for the surface of the plurality of parts. Therefore, the difficulty of mesh subdivision is greatly reduced, and the quantity of positions to be calculated is also greatly reduced, which effectively improves the calculation efficiency.

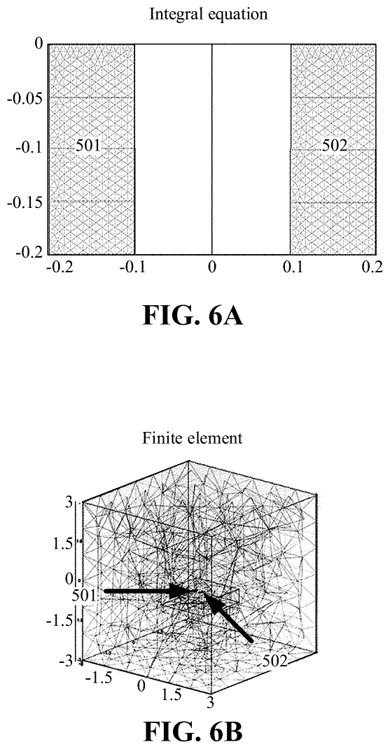

FIG. 5 is a schematic diagram of a capacitance calculation method, according to some embodiments of the present disclosure. Calculation of a capacitance between two pieces of metal is taken as an example. As shown in FIG. 5, two pieces of rectangular metal 501 and 502 are placed on a dielectric substrate, and a capacitance between the two pieces of metal is calculated. FIGS. 6A and 6B illustrate schematic effect diagrams of using an integral equation method and an FEM in a capacitance calculation method respectively, according to some embodiments of the present disclosure. As shown in FIGS. 6A and 6B, when using the integral equation, subdivision needs to be performed on the rectangular metal surface only, while the FEM requires three-dimensional subdivision of the entire space. The reduction in complexity is significant.

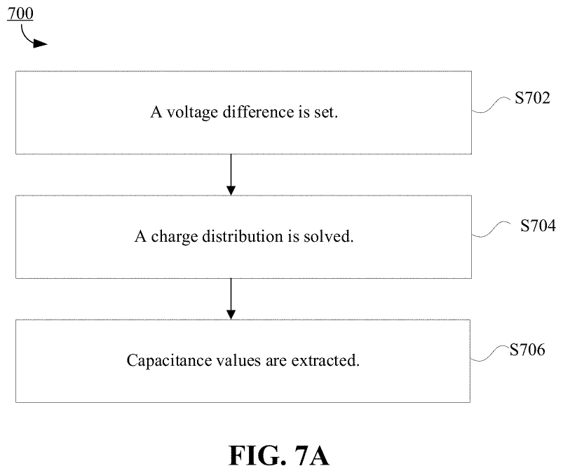

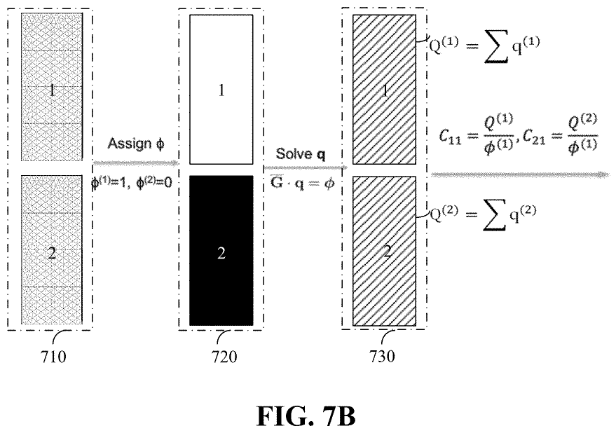

FIG. 7A is a flowchart of an exemplary capacitance calculation method 700, according to some embodiments of the present disclosure. FIG. 7B illustrates a process of calculation for extracting a capacitance parameter using capacitance calculation method 700, according to some embodiments of the present disclosure. As shown in FIG. 7A, the method 700 includes the steps S702 to S706. Referring to FIG. 7A, after mesh subdivision is performed on surfaces of the rectangular metals 1 and 2 (shown in 710 of FIG. 7B), a method for extracting a capacitance parameter can be performed.

At step S702, a voltage difference is set. As shown in 720 of FIG. 7B, the white metal 1 and the black metal 2 indicate that different voltages (potentials ϕ) are set.

At step S704, a charge distribution is solved. As shown in 730 of FIG. 7B, corresponding different charges q⁽¹⁾ and q⁽²⁾ are distributed on the metal 1 and metal 2 with different voltages, where q is obtained by solving G̅·q=ϕ, where G̅ is a matrix constructed by the Green's function. Q⁽¹⁾ is obtained by performing summation on q⁽¹⁾, and Q⁽²⁾ is obtained by performing summation on q⁽²⁾.

At step S706, capacitance values are extracted. Referring to FIG. 7B, the capacitances C₁₁ and C₂₁ are obtained through the formula C=Q/ϕ.

This method may be extended to a plurality of metals, and finally capacitances C between the metals are solved.

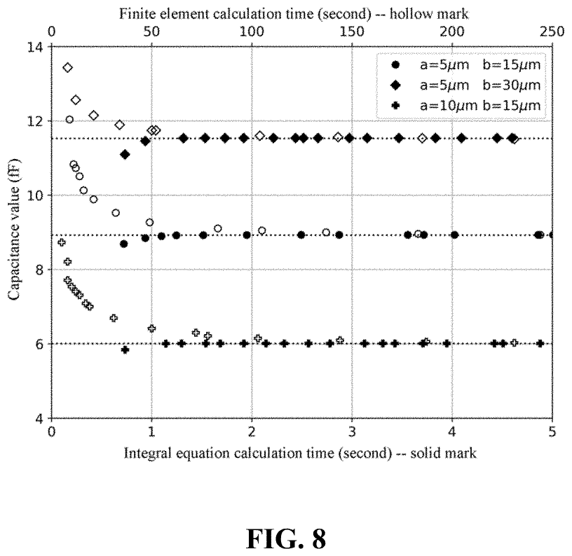

FIG. 8 is a schematic diagram of efficiency obtained based on a capacitance calculation method, according to some embodiments of the present disclosure. As shown in FIG. 8, the capacitance calculation time is significantly reduced using the integral equitation compared with using the FEM, and the efficiency can be improved by nearly 50 times.

Some embodiments of the present disclosure further provide a non-conformal surface boundary triangular mesh refinement method, which is a mesh refinement method that is suitable for simulating boundary singularity and easy to operate. It is especially effective for the calculation of an electric field occupation ratio in a quantum chip.

In the foregoing integral equation solving processes, the mesh refinement method is used. When the numerical method is used to solve a differential equation, mesh subdivision needs to be performed on the environment and boundary. Due to the sudden change of boundary conditions, the solution quantity can have a singular value at the boundary, which makes accurate numerical solution extremely difficult. During analysis on the loss of a quantum chip, an electric field occupation ratio in an ultra-thin region needs to be accurately analyzed.

In view of this, a non-conformal surface boundary triangular mesh refinement method is provided according to the present disclosure, to perform subdivision and refinement on the boundary meshes, and the meshes are optimized layer by layer in an iterative manner. Any curved surface/plane may be optimally approximated, to generate conformal meshes. The meshing method provided by the present disclosure is a further optimization of the calculation expense for general mesh subdivision in an application of a superconducting quantum chip, and can more effectively resolve the related problems in the field of superconducting quantum.

In some embodiments of the present disclosure, an example of performing refinement on a roughly subdivided triangular mesh is provided.

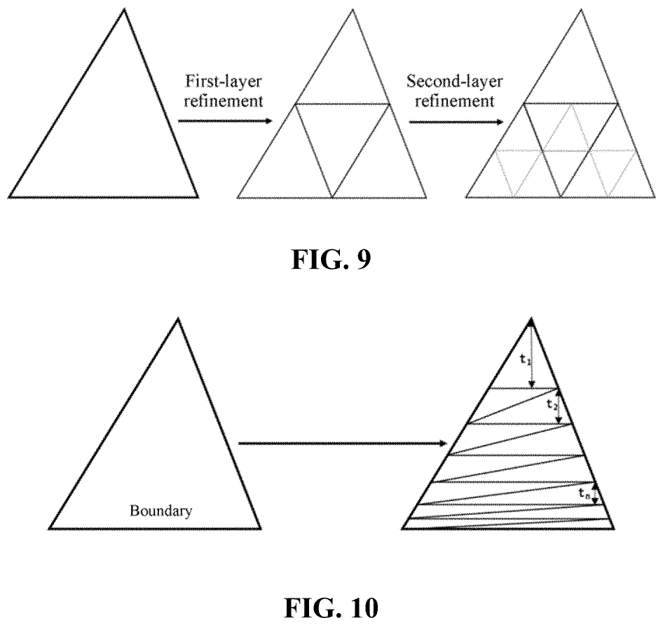

FIG. 9 is a schematic diagram of a uniform refinement solution in a mesh refinement method, according to some embodiments of the present disclosure. As shown in FIG. 9, after a plurality of layers of refinement, a plurality of small meshes with the same aspect ratio can be generated. A triangle on the surface is divided into four small triangles through uniform refinement. The uniform refinement can be used for a plurality of times. Conformality of the meshes can be maintained. If the scheme works only on boundary triangles, non-conformal meshes will be generated. In addition, the quantity of triangles will exponentially increase with the quantity of refinement layers.

FIG. 10 is a schematic diagram of a boundary refinement solution in a mesh refinement method, according to some embodiments of the present disclosure. As shown in FIG. 10, the triangle is divided parallel to the boundary and it is ensured that a triangle height t_i meets t_i/t_{i+1}=constant>1. The meshes closer to the boundary are gradually smaller, which can better represent the singularity at the boundary. A layer-by-layer attenuation scheme is used to divide the triangles at the boundary into a plurality of smaller triangles. In addition, the meshes can maintain locally conformal. The quantity of meshes increases linearly with the quantity of refinement layers, that is, the quantity of triangles increases linearly, and the aspect ratios of the triangles also change gradually.

When either scheme of uniform refinement or boundary refinement is used, the problem of singular point simulation cannot be well solved: only use of uniform refinement will lead to an exponential increase of unknowns and increase the calculation burden; and only use of boundary refinement will result in that the calculation accuracy of non-boundary regions cannot be well controlled.

A mixed meshes refinement method is provided according to the embodiments of the present disclosure. The method uses a mixture of uniform refinement method and boundary refinement method, so that the properties of the methods can be well maintained.

In some embodiments, on a center region of the surface (e.g., non-boundary region) of the plurality of parts of a qubit, the uniform refinement method is used. On a region close to the boundary (e.g., boundary region) of the surface of the plurality of parts, the boundary refinement method is used. Therefore, the two-dimensional mesh subdivision of the surface of the plurality of parts is improved.

In the guideline of the superconducting quantum chip, only the electrostatic field analysis of the planar structure is usually required. Therefore, the optimal approximation of any curved surface is not important, which may cause additional calculation expenses. In addition, electrostatic field analysis is also applicable to non-conformal meshes.

According to the embodiments of the present disclosure, the following beneficial effects can be achieved.

(1) The superconducting qubit simulation is accelerated.

(2) The electric field occupation ratio in a superconducting qubit is accurately calculated.

(3) In the mesh refinement method, a small quantity of uniform refinement layers are used to effectively optimize the accuracy of the non-boundary region, while effectively controlling the quantity of unknowns.

(4) In the mesh refinement method, mesh subdivision at the boundary are arbitrarily refined in the vertical direction, which can greatly improve the calculation accuracy of the boundary, while the unknowns increase linearly and are controlled within a relatively small range.

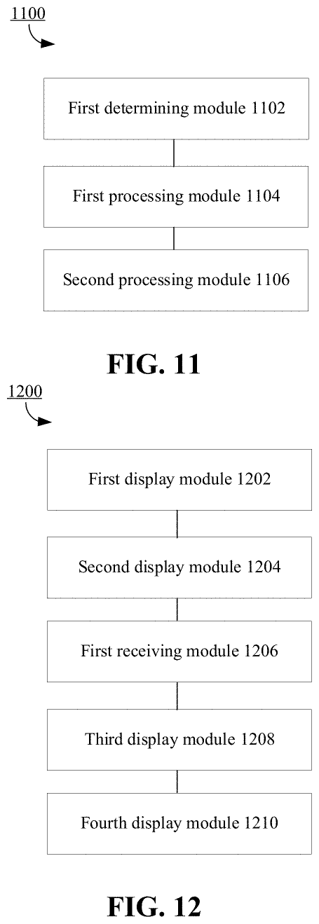

According to some embodiments of the present disclosure, an apparatus 1100 configured to perform the foregoing qubit processing method is further provided. FIG. 11 is a structural block diagram of a qubit processing apparatus 1100, according to some embodiments of the present disclosure. As shown in FIG. 11, the apparatus includes a first determining module 1102, a first processing module 1104, and a second processing module 1106.

The first determining module 1102 is configured to determine a plurality of parts included in a qubit. The first processing module 1104 is connected to the first determining module 1102, and configured to determine electromagnetic interaction between the plurality of parts by using integral equations, to obtain electromagnetic parameters of surfaces of the plurality of parts, where the integral equations respectively use a Green's function to represent the electromagnetic interactions between the plurality of parts. The second processing module 1106 is connected to the first processing module 1104, and configured to perform summation on the electromagnetic parameters of the surfaces of the plurality of parts to obtain an electromagnetic parameter of the qubit.

The first determining module 1102, the first processing module 1104, and the second processing module 1106 correspond to step S202 to step S206 in method 200 shown in FIG. 2, and examples and application scenarios implemented by the three modules and the corresponding steps are the same, but are not limited to the contents disclosed above. It is to be noted that the foregoing modules, as a part of the apparatus, may be run in the computer terminal 100 shown in FIG. 1.

According to some embodiments of the present disclosure, an apparatus 1200 configured to perform the foregoing qubit processing method is further provided. FIG. 12 is a structural block diagram of a qubit processing apparatus 1200, according to some embodiments of the present disclosure. As shown in FIG. 12, the apparatus 1200 includes a first display module 1202, a second display module 1204, a first receiving module 1206, a third display module 1208, and a fourth display module 1210.

The first display module 1202 is configured to display an import control of a qubit on an interaction interface. The second display module 1204 is connected to the first display module 1202, and configured to display an image of the qubit on the interaction interface in response to an operation on the import control. The first receiving module 1206 is connected to the second display module 1204, and configured to receive an instruction to acquire an electromagnetic parameter of the qubit. The third display module 1208 is connected to the first receiving module 1206, and configured to display, in response to the instruction and on the interaction interface, a plurality of parts included in the qubit. The fourth display module 1210 is connected to the third display module 1208, and configured to display the electromagnetic parameter of the qubit on the interaction interface, where the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

The first display module 1202, the second display module 1204, the first receiving module 1206, the third display module 1208, and the fourth display module 1210 correspond to step S302 to step S310 in method 300 shown in FIG. 3, and examples and application scenarios implemented by the plurality of modules and the corresponding steps are the same, but are not limited to the contents disclosed above. It is to be noted that the foregoing modules, as a part of the apparatus, may be run in the computer terminal 100 shown in FIG. 1.

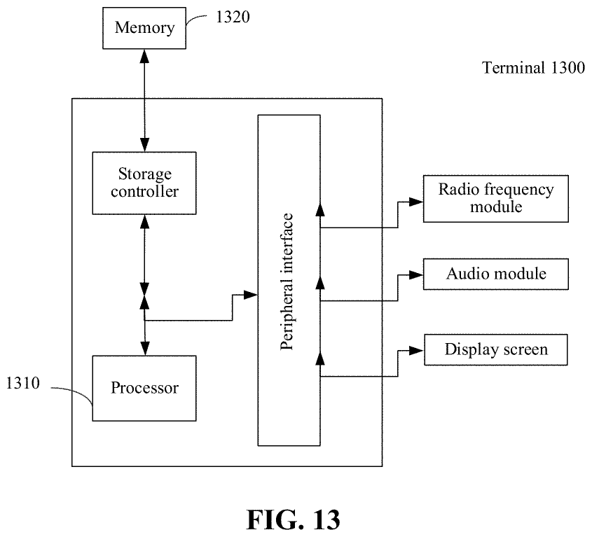

Some embodiments of the present disclosure may provide a computer terminal, and the computer terminal may be any computer terminal device in a computer terminal cluster. FIG. 13 is an apparatus block diagram of an exemplary terminal 1300, according to some embodiments of the present disclosure. In some embodiments, the computer terminal 1300 may be replaced with a terminal device such as a mobile terminal.

In some embodiments, the computer terminal 1300 may be located in at least one of a plurality of network devices in a computer network.

In some embodiments, the computer terminal 1300 may execute program instructions of the following steps in the qubit processing method of an application: determining a plurality of parts included in a qubit; determining electromagnetic interaction between the plurality of parts by using integral equations, to obtain electromagnetic parameters of surfaces of the plurality of parts, where the integral equations respectively use a Green's function to represent the electromagnetic interaction between the plurality of parts; and performing summation on the electromagnetic parameters of the surfaces of the plurality of parts to obtain an electromagnetic parameter of the qubit.

The terminal 1300 includes a memory 1320 and a processor 1310. The memory 1320 may be configured to store a software program and module, for example, a program instruction/module corresponding to the qubit processing method and apparatus in the embodiments of the present disclosure. The processor runs the software program and module stored in the memory, to implement various functional applications and data processing, that is, implement the qubit processing method. The memory may include a high-speed random access memory, and may also include a non-volatile memory, for example, one or more magnetic storage apparatuses, flash memories, or other nonvolatile solid-state memories. In some embodiments, the memory may further include memories remotely disposed relative to the processor, and these remote memories may be connected to the terminal A through a network. The foregoing examples of the network include, but not limited to, the Internet, an intranet, a local area network, a mobile communication network, and a combination thereof.

The processor 1310 may call, by using a transmission apparatus, the information and the application program that are stored in the memory, to perform the following steps: determining a plurality of parts included in a qubit; determining electromagnetic interaction between the plurality of parts by using integral equations, to obtain electromagnetic parameters of surfaces of the plurality of parts, where the integral equations respectively use a Green's function to represent the electromagnetic interaction between the plurality of parts; and performing summation on the electromagnetic parameters of the surfaces of the plurality of parts to obtain an electromagnetic parameter of the qubit.

In some embodiments, the processor 1310 may further execute program code of the following step: the determining electromagnetic interaction between the plurality of parts by using integral equations, to obtain electromagnetic parameters of surfaces of the plurality of parts includes: calculating the electromagnetic parameters of the surfaces of the plurality of parts by using a Gaussian integration method.

In some embodiments, the processor 1310 may further execute program code of the following steps: the determining electromagnetic interaction between the plurality of parts by using integral equations, to obtain electromagnetic parameters of surfaces of the plurality of parts includes: respectively performing two-dimensional mesh subdivision on the surfaces of the plurality of parts to obtain a plurality of meshes; and calculating electromagnetic parameters of the plurality of meshes by using integral equations, to obtain the electromagnetic parameters of the surfaces of the plurality of parts respectively.

In some embodiments, the processor 1310 may further execute program code of the following step: the respectively performing two-dimensional mesh subdivision on the surfaces of the plurality of parts to obtain a plurality of meshes includes: respectively performing two-dimensional mesh subdivision on the surfaces of the plurality of parts by using a mixture of a uniform refinement method and a boundary refinement method, to obtain the plurality of meshes.

In some embodiments, the processor 1310 may further execute program code of the following step: the respectively performing two-dimensional mesh subdivision on the surfaces of the plurality of parts by using a mixture of a uniform refinement method and a boundary refinement method, to obtain the plurality of meshes includes: respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

In some embodiments, the processor 1310 may further execute program instructions of the following step: the meshes obtained through subdivision are triangular meshes, and triangular meshes obtained through subdivision by using the uniform refinement method have the same aspect ratio; and for triangular meshes obtained through subdivision by using the boundary refinement method, an obtained triangular mesh closer to a boundary of the boundary region is smaller, and the triangular meshes have different aspect ratios.

In some embodiments, the processor 1310 may further execute program instructions of the following step: the electromagnetic parameter includes at least one of the following: electric field energy and an electric field occupation ratio.

The processor 1310 may call, by using a transmission apparatus, the information and the application program that are stored in the memory, to perform the following steps: displaying an import control of a qubit on an interaction interface; displaying an image of the qubit on the interaction interface in response to an operation on the import control; receiving an instruction to acquire an electromagnetic parameter of the qubit; displaying, in response to the instruction and on the interaction interface, a plurality of parts included in the qubit; and displaying the electromagnetic parameter of the qubit on the interaction interface, where the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

By using the embodiments of the present disclosure, a solution for qubit processing is provided. By determining a plurality of parts included in a qubit, and determining electromagnetic interaction between the plurality of parts by using integral equations, electromagnetic parameters of surfaces of the plurality of parts are obtained; and by respectively processing the parts efficiently, and then performing summation on the electromagnetic parameters of the surfaces of the plurality of parts, an electromagnetic parameter of the qubit is obtained, thereby resolving the technical problem of an excessively long calculation time caused by a large amount of calculation in a qubit simulation process in the related art.

A person of ordinary skill in the art may understand that, the structure shown in FIG. 13 is only illustrative. The computer terminal may be a terminal device such as a smartphone (such as an Android mobile phone or an iOS mobile phone), a tablet computer, a palmtop computer, a mobile Internet device (MID), or a PAD. FIG. 13 does not constitute a limitation on the structure of the computer terminal. For example, the computer terminal 1300 may further include more or fewer components (such as a network interface and a display apparatus) than those shown in FIG. 13, or has a configuration different from that shown in FIG. 13.

A person of ordinary skill in the art may understand that all or some of the steps of the methods in the foregoing embodiments may be implemented by a program instructing relevant hardware of the terminal device. The program may be stored in a computer-readable storage medium. The storage medium may include a flash disk, a ROM, a RAM, a magnetic disk, an optical disc, and the like.

Some embodiments of the present disclosure further provide a storage medium. In some embodiments, the storage medium may be configured to save the program instructions executed in the qubit processing method provided above.

In some embodiments, the storage medium may be located in any computer terminal in a computer terminal cluster in a computer network, or in any mobile terminal in a mobile terminal cluster.

In some embodiments, the storage medium is configured to store program code for performing the following steps: determining a plurality of parts included in a qubit; determining electromagnetic interaction between the plurality of parts by using integral equations, to obtain electromagnetic parameters of surfaces of the plurality of parts, where the integral equations respectively use a Green's function to represent the electromagnetic interaction between the plurality of parts; and performing summation on the electromagnetic parameters of the surfaces of the plurality of parts to obtain an electromagnetic parameter of the qubit.

In some embodiments, the storage medium is configured to store program code for performing the following step: the determining electromagnetic interaction between the plurality of parts by using integral equations, to obtain electromagnetic parameters of surfaces of the plurality of parts includes: calculating the electromagnetic parameters of the surfaces of the plurality of parts by using a Gaussian integration method.

In some embodiments, the storage medium is configured to store program code for performing the following steps: the determining electromagnetic interaction between the plurality of parts by using integral equations, to obtain electromagnetic parameters of surfaces of the plurality of parts includes: respectively performing two-dimensional mesh subdivision on the surfaces of the plurality of parts to obtain a plurality of meshes; and calculating electromagnetic parameters of the plurality of meshes by using integral equations, to obtain the electromagnetic parameters of the surfaces of the plurality of parts respectively.

In some embodiments, the storage medium is configured to store program code for performing the following step: the respectively performing two-dimensional mesh subdivision on the surfaces of the plurality of parts to obtain a plurality of meshes includes: respectively performing two-dimensional mesh subdivision on the surfaces of the plurality of parts by using a mixture of a uniform refinement method and a boundary refinement method, to obtain the plurality of meshes.

In some embodiments, the storage medium is configured to store program code for performing the following step: the respectively performing two-dimensional mesh subdivision on the surfaces of the plurality of parts by using a mixture of a uniform refinement method and a boundary refinement method, to obtain the plurality of meshes includes: respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

In some embodiments, the storage medium is configured to store program code for performing the following step: the meshes obtained through subdivision are triangular meshes, and triangular meshes obtained through subdivision by using the uniform refinement method have the same aspect ratio; and for triangular meshes obtained through subdivision by using the boundary refinement method, an obtained triangular mesh closer to a boundary of the boundary region is smaller, and the triangular meshes have different aspect ratios.

In some embodiments, the storage medium is configured to store program code for performing the following step: the electromagnetic parameter includes at least one of the following: electric field energy and an electric field occupation ratio.

In some embodiments, the storage medium is configured to store program code for performing the following steps: displaying an import control of a qubit on an interaction interface; displaying an image of the qubit on the interaction interface in response to an operation on the import control; receiving an instruction to acquire an electromagnetic parameter of the qubit; displaying, in response to the instruction and on the interaction interface, a plurality of parts included in the qubit; and displaying the electromagnetic parameter of the qubit on the interaction interface, where the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

The embodiments may further be described using the following clauses:

1. A qubit processing method, comprising:

determining a plurality of parts comprised in a qubit;

determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and

performing summation on the electromagnetic parameters of the surfaces of the plurality of parts to obtain an electromagnetic parameter of the qubit.

2. The method according to clause 1, wherein determining electromagnetic interactions between the plurality of parts by using integral equations, to obtain electromagnetic parameters of surfaces of the plurality of parts comprises:

calculating the electromagnetic parameters of the surfaces of the plurality of parts by using a Gaussian integration method.

3. The method according to clause 1, wherein determining electromagnetic interaction between the plurality of parts by using integral equations, to obtain electromagnetic parameters of surfaces of the plurality of parts comprises:

respectively performing two-dimensional mesh subdivision on the surfaces of the plurality of parts to obtain a plurality of meshes; and

calculating electromagnetic parameters of the plurality of meshes by using integral equations, to obtain the electromagnetic parameters of the surfaces of the plurality of parts respectively.

4. The method according to clause 3, wherein respectively performing two-dimensional mesh subdivision on the surfaces of the plurality of parts to obtain a plurality of meshes comprises:

respectively performing two-dimensional mesh subdivision on the surfaces of the plurality of parts by using a mixture of a uniform refinement method and a boundary refinement method, to obtain the plurality of meshes.

5. The method according to clause 4, wherein respectively performing two-dimensional mesh subdivision on the surfaces of the plurality of parts by using a mixture of a uniform refinement method and a boundary refinement method, to obtain the plurality of meshes comprises:

respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

6. The method according to clause 5, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.

7. The method according to any one of clause 1 to 6, wherein the electromagnetic parameter comprises at least one of electric field energy and an electric field occupation ratio.

8. An apparatus for performing qubit processing, the apparatus comprising:

a memory configured to store instructions; and

one or more processors configured to execute the instructions to cause the apparatus to perform:

determining a plurality of parts comprised in a qubit;

determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and

performing summation on the electromagnetic parameters of the surfaces of the plurality of parts to obtain an electromagnetic parameter of the qubit.

9. The apparatus according to clause 7, wherein in determining electromagnetic interactions between the plurality of parts by using integral equations, to obtain electromagnetic parameters of surfaces of the plurality of parts, the one or more processors are further configured to execute the instructions to cause the apparatus to perform:

calculating the electromagnetic parameters of the surfaces of the plurality of parts by using a Gaussian integration method.

10. The apparatus according to clause 7, wherein in determining electromagnetic interaction between the plurality of parts by using integral equations, to obtain electromagnetic parameters of surfaces of the plurality of parts, the one or more processors are further configured to execute the instructions to cause the apparatus to perform:

respectively performing two-dimensional mesh subdivision on the surfaces of the plurality of parts to obtain a plurality of meshes; and

calculating electromagnetic parameters of the plurality of meshes by using integral equations, to obtain the electromagnetic parameters of the surfaces of the plurality of parts respectively.

11. The apparatus according to clause 10, wherein in respectively performing two-dimensional mesh subdivision on the surfaces of the plurality of parts to obtain a plurality of meshes, the one or more processors are further configured to execute the instructions to cause the apparatus to perform:

respectively performing two-dimensional mesh subdivision on the surfaces of the plurality of parts by using a mixture of a uniform refinement method and a boundary refinement method, to obtain the plurality of meshes.

12. The apparatus according to clause 11, wherein in respectively performing two-dimensional mesh subdivision on the surfaces of the plurality of parts by using a mixture of a uniform refinement method and a boundary refinement method, the one or more processors are further configured to execute the instructions to cause the apparatus to perform:

respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

13. The apparatus according to clause 12, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.

14. The apparatus according to any one of clauses 8 to 13, wherein the electromagnetic parameter comprises at least one of electric field energy and an electric field occupation ratio.

15. A non-transitory computer readable medium that stores a set of instructions that is executable by one or more processors of an apparatus to cause the apparatus to initiate a method for performing qubit processing, the method comprising:

determining a plurality of parts comprised in a qubit;

determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and

performing summation on the electromagnetic parameters of the surfaces of the plurality of parts to obtain an electromagnetic parameter of the qubit.

16. The non-transitory computer readable medium of clause 15, wherein the set of instructions that is executable by one or more processors of an apparatus to cause the apparatus to further perform:

calculating the electromagnetic parameters of the surfaces of the plurality of parts by using a Gaussian integration method.

17. The non-transitory computer readable medium of clause 15, wherein the set of instructions that is executable by one or more processors of an apparatus to cause the apparatus to further perform:

respectively performing two-dimensional mesh subdivision on the surfaces of the plurality of parts to obtain a plurality of meshes; and

calculating electromagnetic parameters of the plurality of meshes by using integral equations, to obtain the electromagnetic parameters of the surfaces of the plurality of parts respectively.

18. The non-transitory computer readable medium of clause 17, wherein the set of instructions that is executable by one or more processors of an apparatus to cause the apparatus to further perform:

respectively performing two-dimensional mesh subdivision on the surfaces of the plurality of parts by using a mixture of a uniform refinement method and a boundary refinement method, to obtain the plurality of meshes.

19. The non-transitory computer readable medium of clause 18, wherein the set of instructions that is executable by one or more processors of an apparatus to cause the apparatus to further perform:

respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

20. The non-transitory computer readable medium of clause 19, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.

21. A qubit processing method, comprising:

displaying an import control of a qubit on an interaction interface;

displaying an image of the qubit on the interaction interface in response to an operation on the import control;

receiving an instruction to acquire an electromagnetic parameter of the qubit;

displaying, in response to the instruction and on the interaction interface, a plurality of parts comprised in the qubit; and

displaying the electromagnetic parameter of the qubit on the interaction interface, wherein the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

22. An apparatus for performing qubit processing, the apparatus comprising:

a memory configured to store instructions; and

one or more processors configured to execute the instructions to cause the apparatus to perform:

displaying an import control of a qubit on an interaction interface;

displaying an image of the qubit on the interaction interface in response to an operation on the import control;

receiving an instruction to acquire an electromagnetic parameter of the qubit;

displaying, in response to the instruction and on the interaction interface, a plurality of parts comprised in the qubit; and

displaying the electromagnetic parameter of the qubit on the interaction interface, wherein the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

23. A non-transitory computer readable medium that stores a set of instructions that is executable by one or more processors of an apparatus to cause the apparatus to initiate a method for performing qubit processing, the method comprising:

displaying an import control of a qubit on an interaction interface;

displaying an image of the qubit on the interaction interface in response to an operation on the import control;

receiving an instruction to acquire an electromagnetic parameter of the qubit;

displaying, in response to the instruction and on the interaction interface, a plurality of parts comprised in the qubit; and

displaying the electromagnetic parameter of the qubit on the interaction interface, wherein the electromagnetic parameter is obtained by performing summation on electromagnetic parameters of surfaces of the plurality of parts, the electromagnetic parameters of the surfaces of the plurality of parts are obtained after electromagnetic interaction between the plurality of parts is determined by using integral equations, and the integral equations use a Green's function to represent the electromagnetic interaction between the plurality of parts.

In some embodiments, a non-transitory computer-readable storage medium including instructions is also provided, and the instructions may be executed by a device, for performing the above-described methods. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same. The device may include one or more processors (CPUs), an input/output interface, a network interface, and/or a memory.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

It is appreciated that the above-described embodiments can be implemented by hardware, or software (program codes), or a combination of hardware and software. If implemented by software, it may be stored in the above-described computer-readable media. The software, when executed by the processor can perform the disclosed methods. The computing units and other functional units described in this disclosure can be implemented by hardware, or software, or a combination of hardware and software. One of ordinary skill in the art will also understand that multiple ones of the above-described modules/units may be combined as one module/unit, and each of the above-described modules/units may be further divided into a plurality of sub-modules/sub-units.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A qubit processing method, comprising:
determining a plurality of parts comprised in a qubit;
determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and
performing summation on the electromagnetic parameters of the surfaces of the plurality of parts to obtain an electromagnetic parameter of the qubit.

2. The method according to claim 1, wherein determining electromagnetic interactions between the plurality of parts by using integral equations, to obtain electromagnetic parameters of surfaces of the plurality of parts comprises:
calculating the electromagnetic parameters of the surfaces of the plurality of parts by using a Gaussian integration method.

3. The method according to claim 1, wherein determining electromagnetic interaction between the plurality of parts by using integral equations, to obtain electromagnetic parameters of surfaces of the plurality of parts comprises:
respectively performing two-dimensional mesh subdivision on the surfaces of the plurality of parts to obtain a plurality of meshes; and
calculating electromagnetic parameters of the plurality of meshes by using integral equations, to obtain the electromagnetic parameters of the surfaces of the plurality of parts respectively.

4. The method according to claim 3, wherein respectively performing two-dimensional mesh subdivision on the surfaces of the plurality of parts to obtain a plurality of meshes comprises:
respectively performing two-dimensional mesh subdivision on the surfaces of the plurality of parts by using a mixture of a uniform refinement method and a boundary refinement method, to obtain the plurality of meshes.

5. The method according to claim 4, wherein respectively performing two-dimensional mesh subdivision on the surfaces of the plurality of parts by using a mixture of a uniform refinement method and a boundary refinement method, to obtain the plurality of meshes comprises:
respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

6. The method according to claim 5, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.

7. The method according to claim 1, wherein the electromagnetic parameter comprises at least one of electric field energy and an electric field occupation ratio.

8. An apparatus for performing qubit processing, the apparatus comprising:
a memory configured to store instructions; and
one or more processors configured to execute the instructions to cause the apparatus to perform:
determining a plurality of parts comprised in a qubit;
determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and
performing summation on the electromagnetic parameters of the surfaces of the plurality of parts to obtain an electromagnetic parameter of the qubit.

9. The apparatus according to claim 7, wherein in determining electromagnetic interactions between the plurality of parts by using integral equations, to obtain electromagnetic parameters of surfaces of the plurality of parts, the one or more processors are further configured to execute the instructions to cause the apparatus to perform:
calculating the electromagnetic parameters of the surfaces of the plurality of parts by using a Gaussian integration method.

10. The apparatus according to claim 7, wherein in determining electromagnetic interaction between the plurality of parts by using integral equations, to obtain electromagnetic parameters of surfaces of the plurality of parts, the one or more processors are further configured to execute the instructions to cause the apparatus to perform:
respectively performing two-dimensional mesh subdivision on the surfaces of the plurality of parts to obtain a plurality of meshes; and
calculating electromagnetic parameters of the plurality of meshes by using integral equations, to obtain the electromagnetic parameters of the surfaces of the plurality of parts respectively.

11. The apparatus according to claim 10, wherein in respectively performing two-dimensional mesh subdivision on the surfaces of the plurality of parts to obtain a plurality of meshes, the one or more processors are further configured to execute the instructions to cause the apparatus to perform:
respectively performing two-dimensional mesh subdivision on the surfaces of the plurality of parts by using a mixture of a uniform refinement method and a boundary refinement method, to obtain the plurality of meshes.

12. The apparatus according to claim 11, wherein in respectively performing two-dimensional mesh subdivision on the surfaces of the plurality of parts by using a mixture of a uniform refinement method and a boundary refinement method, the one or more processors are further configured to execute the instructions to cause the apparatus to perform:
respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

13. The apparatus according to claim 12, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.

14. The apparatus according to claim 8, wherein the electromagnetic parameter comprises at least one of electric field energy and an electric field occupation ratio.

15. A non-transitory computer readable medium that stores a set of instructions that is executable by one or more processors of an apparatus to cause the apparatus to initiate a method for performing qubit processing, the method comprising:
determining a plurality of parts comprised in a qubit;
determining electromagnetic interactions between the plurality of parts by using integral equations, to obtain electromagnetic parameters of surfaces of the plurality of parts, wherein the integral equations respectively use a Green's function to represent the electromagnetic interactions between the plurality of parts; and
performing summation on the electromagnetic parameters of the surfaces of the plurality of parts to obtain an electromagnetic parameter of the qubit.

16. The non-transitory computer readable medium of claim 15, wherein the set of instructions that is executable by one or more processors of an apparatus to cause the apparatus to further perform:
calculating the electromagnetic parameters of the surfaces of the plurality of parts by using a Gaussian integration method.

17. The non-transitory computer readable medium of claim 15, wherein the set of instructions that is executable by one or more processors of an apparatus to cause the apparatus to further perform:
respectively performing two-dimensional mesh subdivision on the surfaces of the plurality of parts to obtain a plurality of meshes; and
calculating electromagnetic parameters of the plurality of meshes by using integral equations, to obtain the electromagnetic parameters of the surfaces of the plurality of parts respectively.

18. The non-transitory computer readable medium of claim 17, wherein the set of instructions that is executable by one or more processors of an apparatus to cause the apparatus to further perform:
respectively performing two-dimensional mesh subdivision on the surfaces of the plurality of parts by using a mixture of a uniform refinement method and a boundary refinement method, to obtain the plurality of meshes.

19. The non-transitory computer readable medium of claim 18, wherein the set of instructions that is executable by one or more processors of an apparatus to cause the apparatus to further perform:
respectively performing two-dimensional mesh subdivision on non-boundary regions of the surfaces of the plurality of parts by using the uniform refinement method and respectively performing two-dimensional mesh subdivision on boundary regions of the surfaces of the plurality of parts by using the boundary refinement method, to obtain the plurality of meshes.

20. The non-transitory computer readable medium of claim 19, wherein the meshes obtained through subdivision are triangular meshes, and triangular meshes obtained through subdivision by using the uniform refinement method have a same aspect ratio; and for triangular meshes obtained through subdivision by using the boundary refinement method, an obtained triangular mesh closer to a boundary of the boundary region is smaller, and the triangular meshes have different aspect ratios.
